(19) United States
(12) Patent Application Publication
(10) Pub. No.: US 2010/0098856 A1
(43) Pub. Date: Apr. 22, 2010

(54) METHOD FOR FABRICATING I -III-VI2 COMPOUND THIN FILM USING SINGLE METAL-ORGANIC CHEMICAL VAPOR DEPOSITION PROCESS

(75) Inventor: In-hwan Choi, Seoul (KR)

Correspondence Address: OBLON, SPIVAK, MCCLELLAND MAIER & NEUSTADT, L.L.P., 1940 DUKE STREET, ALEXANDRIA, VA, 22314, US

(73) Assignee: IN-SOLAR TECH CO., LTD., Seoul (KR)

(21) Appl. No.: 12/530,881

(22) PCT Filed: Feb. 22, 2008
(86) PCT No.: PCT/KR2008/001041

§ 371 Date: Sep. 11, 2009

(30) Foreign Application Priority Data
Mar. 13, 2007 (KR) 10-2007-0024682

(51) Int. Cl. C23C 16/44

(52) U.S. Cl. 427/255.28

(57) ABSTRACT

Disclosed herein is a method for producing a 1-IH-VI2 compound thin film on a substrate through a single Metal Organic Chemical Vapor Deposition (MOCVD) process, wherein a Group III element and Group VI element-containing single precursor, a Group I metal-containing precursor, and a Group VI element-containing precursor or a Group VI element-containing gas are concurrently supplied to a substrate and subjected to MOCVD to form a I-III-VI2 compound thin film on the substrate. The method employs a single deposition process to form the thin film and is thus provides a more economical, simplified process as compared to conventional methods. In addition, the method is capable of producing a thin film with an even surface and few or no inner pores, and, advantageously, is thus useful as a light-absorbing layer for a solar cell.

### BACKGROUND OF THE INVENTION

1. Field of the Invention

The present invention relates to a method for a producing an I-III-VI₂ compound thin film using a single Metal Organic Chemical Vapor Deposition (MOCVD) process. More specifically, the present invention relates to a method for producing an I-III-VI₂ compound thin film in which a high-quality I-III-VI₂ compound thin film with an even surface can be formed on a substrate using a single MOCVD process and production efficiency can be improved via reduced production time.

2. Description of the Related Art

Generally, Group I-III-VI₂ (Group I: Ag, Cu; Group III: Al, Ga, In; and Group VI: S, Se and Te) compound semiconductors have a chalcopyrite structure at ambient temperature and atmospheric pressure. Due to their wide variation in properties via variation in constituent atoms, I-III-VI₂ compound semiconductors are widely utilized in a variety of applications.

Since Group I-III-VI₂ compound semiconductors were first synthesized by Hahn et al. in 1953 and their potential utilization as semiconductors was suggested by Goodman et al., they have been utilized in applications including infrared detectors (CuInSe₂, CuInS₂), light emitting diodes (CuInSe₂, CuGaS₂), nonlinear optical devices (AgGaS₂, AgGaSe₂), solar cells [CuInSe₂ (hereinafter, referred to as “CIS”) or CuIn₁₋ₓGaₓSe₂ (hereinafter, referred to as “CICS”)] and the like.

The AgGaS₂ compound semiconductors used in nonlinear optical devices have an energy band gap of 2.72 eV at low temperature (2K), a high birefringence magnitude, as compared to other semiconductors, and a high transmissivity in the wide wavelength range of 0.45 to 13 μm, and is suitable for second harmonic generation in the wavelength range of 1.8 to 11 μm.

Since the CuGaS₂ compound semiconductors used in light emitting diodes have an energy band gap of 2.53 eV at low temperature (2K) and exhibit only p-type conduction, they are combined with CdS that exhibits only n-type conduction to produce heterojuctions and thereby to fabricate high-efficiency light emitting diodes.

Since the CIS compound semiconductors used in solar cells have an energy band gap of about 1 eV at ambient temperature and exhibit a linear optical absorption coefficient 10-100 times those of other semiconductors, they have drawn a great deal of attention as absorbers of for use in solar cells.

In particular, unlike conventional crystalline silicon solar cells, CIS thin film solar cells can be produced with low thickness, less than 10 microns, and exhibit stability in long-term use. Furthermore, as CIS thin film solar cells have the highest energy conversion efficiency (i.e., 19.5%) among commonly used thin film-type solar cells, the CIS thin film solar cells are noted for their low-cost and high-efficiency, and are widely available commercially, thereby being capable of supplanting conventional silicon crystalline solar cells.

As such, in spite of the possibility of wide utilization in various applications, in practice, the Group I-III-VI₂ compounds cannot be widely utilized due to difficulties with producing high-quality and economical thin films.

As methods for developing Group I-III-VI₂ compound single crystals, there are melting, chemical vapor transport using iodine, etc. These methods have thus far been entirely experimental and crystals obtained thereby have yet to be commercialized.

Several methods for producing Group I-III-VI₂ compound semiconductor thin films have been suggested to date. In particular, methods for producing CIS-based thin films have been disclosed. For example, U.S. Pat. No. 4,523,051 discloses a method for depositing atoms on a substrate by concurrently evaporating the atoms under vacuum. However, disadvantageously, the inability to produce thin films on a large scale and the difficulty of realizing mass-production make this method uneconomical.

As another example, U.S. Pat. No. 4,798,660 suggests a method for fabricating Cu—In metal thin films by selenization, comprising depositing Cu—In metal thin films by sputtering and heating the thin films under a selenium-containing gas (e.g., H₂Se) atmosphere. This method enables large-area, mass-production and is thus commercially available now. However, this method has problems in that high-quality thin films and multilayer thin films cannot be fabricated.

Other methods include electrodeposition and molecular beam epitaxy (MBE). These methods have problems in that since high-quality thin films cannot be obtained, or if any, economical efficiency is considerably low, the methods are unsuitable for commercial use.

Accordingly, in an attempt to mass-produce high-quality Group I-III-VI₂ compound (including CIS) semiconductors, Metal Organic Chemical Vapor Deposition (hereinafter referred to as “MOCVD”), which is generally used in conventional semiconductor processes, is being used.

In this regard, Korean Patent Nos. 495,924 and 495,925 issued to the present applicant disclose a method for produce I-III-VI₂ compound (e.g., CuInSe₂) thin films with a desired equivalent ratio by MOCVD employing appropriate precursors. The method comprises forming an InSe thin film on a molybdenum (Mo) substrate using an In—Se precursor, depositing copper (Cu) on the InSe thin film to convert the InSe thin film to a Cu₂Se thin film, and re-supplying an InSe source to the Cu₂Se thin film to obtain a CuInSe₂ thin film. With this method, it is possible to easily produce high-quality thin films with a composition substantially equivalent to a stoichiometric ratio in a relatively simple process. Disadvantageously, however, the method requires large amounts of a high-priced Group III element (e.g. indium).

Korean Patent Application No. 2006-0055064, filed by the present applicant to solve the aforementioned problems, discloses a method for producing an I-III-VI₂ compound thin film on a substrate comprising: depositing a single precursor containing Group III and VI elements on a substrate by Metal Organic Chemical Vapor Deposition (MOCVD) to form a Group III-VI or III₂-VI₃ compound thin film; depositing a Group I element-containing precursor on the III-VI or III₂-VI₃ compound thin film by MOCVD to form an I-III-VI compound thin film; and heating the I-III-VI compound thin film under a Group VI element-containing gas atmosphere or depositing a Group VI element-containing precursor on the I-III-VI compound thin film by MOCVD to form an I-III-VI₂compound thin film.

This method is economic and efficient in that a high-quality I-III-VI₂ compound thin film with a composition substantially equivalent to a stoichiometric ratio can be produced without unnecessary waste of the expensive Group III element. Accordingly, the method is highly applicable to production of CIS thin films used as a light-absorbing layer for a solar cell.

However, methods employing a multi-step process to form the final thin film suffer from a long total production time, surface unevenness and generation of inner pores in the developing film. The reason for non-uniform development of the CIGS thin film will be illustrated in more detail. In the first step to form a CIS or CIGS thin film, in an initial state, the Group III-VI thin film is developed in the form of randomly arranged bars, and with the passage of time, the thin film is gradually developed in the form of randomly arranged thin hexagonal plates. After the second and third steps, the thin film is converted into I-III-VI₂ crystal particles. The final I-III-VI₂ compound thin film has a non-uniform surface and inner pores. Variation in surface morphology of the thin film is shown in FIG. 1.

As known, the method for producing solar cells comprises depositing CdS as a buffer layer to a thickness of 50 nm on CIGS as an absorbing layer, and sequentially depositing ZnO and Al-doped ZnO as a window layer thereon, to form a p-i-n junction. Accordingly, when solar cells are produced from CIGS thin films having an uneven surface, the buffer and window layers cannot be uniformly applied to the CIGS absorbing layer and thus uniform junctions cannot be obtained. In this case, since inner short-circuits occur, solar cells with high energy conversion efficiency cannot be produced.

For this reason, as a result of intensive research on methods for producing CIGS thin films with an even surface, the present inventors have discovered that when CIGS thin films are produced though a single-step process, as opposed to a multi-step process used in conventional methods for producing thin films, the final CIGS thin films have an even surface and production efficiency can be improved via reduced production time. Accordingly, the present invention is based on this discovery.

### SUMMARY OF THE INVENTION

Therefore, the present invention has been made in view of the above problems of the prior art, and it is one aspect of the present invention to provide a method for producing an I-III-VI₂ compound thin film on a substrate using a single Metal Organic Chemical Vapor Deposition (MOCVD) process in which a high-quality I-III-VI₂ compound thin film with an even surface can be formed on a substrate using a single MOCVD process and production efficiency can be improved via reduced production time.

It is another aspect of the present invention to provide an absorbing layer for a solar cell, comprising the I-III-VI₂ compound thin film produced by the method.

In accordance with one aspect of the present invention for achieving the above objects, there is provided a method for producing a I-III-VI₂ compound thin film on a substrate through a single Metal Organic Chemical Vapor Deposition (MOCVD) process, wherein a Group III element and Group VI element-containing single precursor, a Group I metal-containing precursor, and a Group VI element-containing precursor or a Group VI element-containing gas are concurrently supplied to a substrate and subjected to MOCVD to form a I-III-VI₂ compound thin film on the substrate.

In accordance with another aspect of the present invention, there is provided an absorbing layer for a solar cell, comprising the I-III-VI₂ compound thin film produced by the method.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a schematic diagram illustrating morphology variation of an InSe thin film developed with passage of time in a first process and a CIS thin film formed by Ce deposition, in the production of a CuInSe₂ or CuInGaSe₂ thin film according to a conventional method;

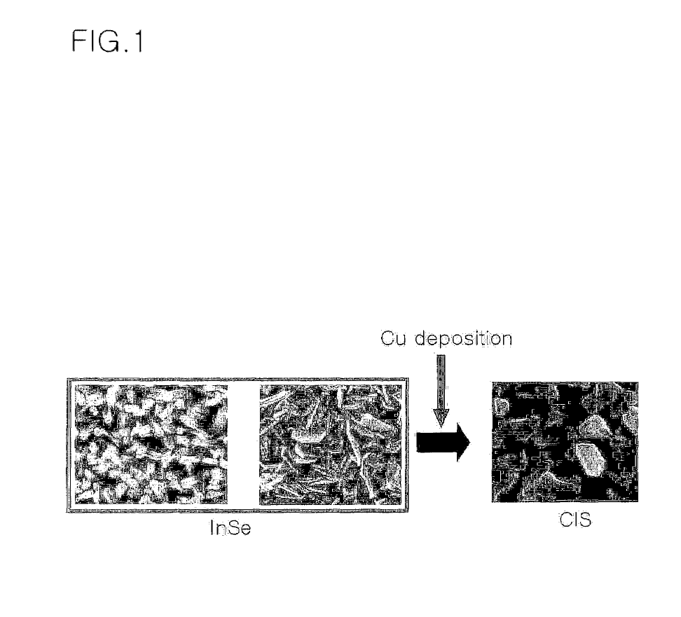

FIG. 2 is a schematic diagram illustrating a method for producing a I-III-VI₂ compound thin film according to a first embodiment of the present invention;

FIG. 3 is a schematic diagram illustrating an example of CuInSe₂ compound thin film production according to a first embodiment of the present invention;

FIG. 4 is a schematic diagram illustrating a method for producing an I-III₁₋ₓIII′ₓ-VI₂ compound thin film according to a second embodiment of the present invention;

FIG. 5 is a schematic diagram illustrating one example of CuIn₁₋ₓGaₓSe₂ compound thin film production according to the second embodiment of the present invention;

FIG. 6 is a schematic diagram illustrating another example of CuIn₁₋ₓGaₓSe₂ compound thin film production according to the second embodiment of the present invention;

FIG. 7 is a schematic diagram illustrating a method for producing a I-III-(VI_{1-y}-VI′_{y})₂ compound thin film according to a third embodiment of the present invention;

FIG. 8 is a schematic diagram illustrating one example of CuIn(Se_{1-y}S_{y})₂ compound thin film production according to the third embodiment of the present invention;

FIG. 9 is a schematic diagram illustrating a method for producing an I-III₁₋ₓIII′ₓ-(VI_{1-y}-VI′_{y})₂ compound thin film according to a fourth embodiment of the present invention;

FIG. 10 is a schematic diagram illustrating one example of CuIn₁₋ₓGaₓ(Se_{1-y}S_{y})₂ compound thin film production according to the fourth embodiment of the present invention;

FIGS. 11 and 12 are SEM surface and cross-section images of the CuInSe₂ thin film produced in Thin Film Production Example 1, respectively;

FIGS. 13 and 14 are SEM surface and cross-section images of the CuInSe₂ thin film produced in Thin Film Production Comparative Example 1 according to the conventional method, respectively;

FIG. 15 is a graph showing XRD patterns of the CuInSe₂ and CuIn_{0.65}Ga_{0.35}Se₂ (x=0.35) thin films developed in Thin Film Production Examples 1 and 2 according to the present invention; and

FIG. 16 is a graph showing Raman spectra of the CuInSe₂ and CuIn_{0.65}Ga_{0.35}Se₂ (x=0.35) thin films developed in Thin Film Production Examples 1 and 2 according to the present invention.

### DESCRIPTION OF THE PREFERRED EMBODIMENTS

The present invention will now be described in greater detail.

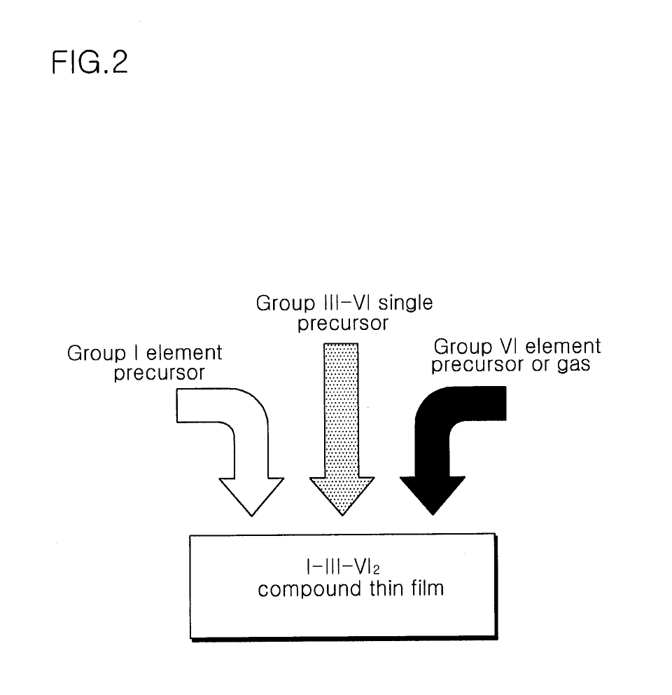

FIG. 2 is a schematic diagram illustrating a method for producing a I-III-VI₂ compound thin film according to a first embodiment of the present invention.

As shown in FIG. 2, according to the first embodiment of the present invention, a Group III element and VI element-containing single precursor, a Group I metal-containing precursor, and a Group VI element-containing precursor or gas are concurrently supplied to the substrate and subjected to MOCVD to form an I-III-VI₂ compound thin film through a single MOCVD process.

That is to say, the present invention is different from the prior art in that the present invention employs a single-step process to form a final thin film, while the prior art employs a multi-step process to form the same. The term “to concurrently supply precursors and gas” used herein means that respective precursors and gas are simultaneously or sequentially supplied by simultaneous or sequential opening of the precursor-containing bubblers and gas supplier. In other words, in an initial thin film development stage, all the precursors and gases required to form the targeted thin film are substantially concurrently fed to the substrate.

The Group I element as used herein includes copper (Cu) or silver (Ag), and covers all Group I elements on the Periodic Table. The Group III element as used herein includes aluminum (Al), gallium (Ga) or indium (In), and covers all Group elements III on the Periodic Table. The Group VI element as used herein includes selenium (Se), sulfur (S) or tellurium (Te), and covers all Group VI elements on the Periodic Table. Preferably, the Group I element is Cu or Ag, the Group III element is selected from In, Ga and Al, and the Group VI element is selected from Se, Te and S.

The present invention employs MOCVD, which is generally used to form a thin film on a substrate. In the present invention, I-III-VI₂ compound thin films are formed through a single MOCVD process by installing a plurality of respective precursor-containing bubblers in a low-pressure MOCVD system and simultaneously or sequentially operating the bubblers.

Examples of the substrate that can be used in the present invention include substrates in which molybdenum (Mo) metal is deposited on a commonly used soda glass substrate, and substrates in which Mo metal is deposited on a film composed of a thin flexible stainless steel or a highly heat-resistant polymer compound (e.g. Kapton or polimide). If needed, a variety of known substrates can be used.

The Group III and VI element-containing single precursor may be a single precursor commonly used in the art. For example, the single precursor may be selected from those that have a structure of [R₂M(μ-ER′)]₂, wherein M is a Group III metal element selected from In, Ga and Al; R and R′ are each independently C₁-C₆ alkyl; E is a Group VI chalcogen element selected from S, Se and Te; and μ indicates a double-bond between the Group VI element and the Group III element.

Specific examples of [R₂M(μ-ER′)]₂ include [Me₂In(μ-SeMe)]₂, [Me₂Ga(μ-SeMe)]₂, [Me₂In(μ-SMe)]₂, [Me₂Ga(μ-SMe)]₂, [Me₂In(μ-TeMe)]₂, [Me₂Ga(μ-TeMe)]₂, [Et₂In(μ-SeEt)]₂, [Et₂Ga(μ-SeEt)]₂, [Et₂In(μ-TeEt)]₂ and [Et₂In(μ-SEt)]₂. In the Formulae, Me is methyl and Et is ethyl. Furthermore, the single precursor is not necessarily limited thereto and those skilled in the art will appreciate that the use of various other single precursors is possible.

The Group I metal-containing precursor may be selected from those commonly used in the art. For example, the Group I metal-containing precursor may be a monovalent Cu precursor having a structure of (hfac)I(DMB). In the Formula, hfac is an abbreviation for hexafluoroacetylaceto and DMB is an abbreviation for 3,3-dimethyl-1-butene. Furthermore, the Group I metal-containing precursor is not necessarily restricted thereto and those skilled in the art will appreciate that the use of other single precursors is possible.

The Group VI element-containing precursor may have a structure of R₂E (wherein E is a Group VI chalcogen element selected from S, Se and Te; and R is C₁-C₆ alkyl). Examples of the R₂E precursor include (C₂H₅)₂Se, (CH₃)₂Se, (C₂H₅)₂S, (CH₃)₂S, (C₂H₅)₂Te and (CH₃)₂Te, and those skilled in the art will appreciate that the use of other single precursors is possible.

The Group VI element-containing gas that can be used, instead of the Group VI element-containing precursor, includes those that have a structure of H₂E (wherein, E is a Group VI chalcogen element selected from Se, S and Te). Specifically, the Group VI element-containing gas is selected from H₂S, H₂Se and H₂Te. For example, an H₂Se gas must be used to form a selenium (Se) compound such as CuInSe₂.

As mentioned above, the Group III element and Group VI element-containing single precursor, the Group I metal-containing precursor, and the Group VI element-containing precursor or gas are concurrently supplied on the substrate and subjected to MOCVD to form an I-III-VI₂ compound thin film. At this time, it is preferable that the Group III element and Group VI element-containing single precursor firstly reaches the substrate, in order to improve a bonding force between the thin film and the substrate.

Comparing the method according to the first embodiment with the method according to the patent application filed by the present applicant prior to the present application (referred to as “prior art”), the prior art employs a multi-step deposition process to form the final I-III-VI₂ compound thin film, but the present invention enables the final I-III-VI₂ compound thin film to be readily formed through a single-step process, thus leading to simplified production process and reduced production time, and realizing mass-production at a low cost. Furthermore, since the thin film begins to develop in the form of single I-III-VI₂ crystals on an early development stage, it finally has high quality, few inner pores and an even surface.

The I-III-VI₂ compound thin film thus produced may be utilized in a variety of applications including absorbing layers for solar cells according to properties of the thin film. As compared to conventional methods for producing a thin film to obtain CIS-type absorbing layers for solar cells, the present method employs a simple deposition process to form the thin film at low cost. In addition, the thin film obtained by the method has an even surface and no inner pores, and is thus highly useful as a high-efficiency solar cell absorber.

Examples of the I-III-VI₂ compound thin film thus formed include CuAlSe₂, CuGaSe₂, CuInSe₂, AgAlSe₂, AgGaSe₂, AgInSe₂, CuAlS₂, CuGaS₂, CuInS₂, AgAlS₂, AgGaS₂, AgInS₂, CuAlTe₂, CuGaTe₂, CuInTe₂, AgAlTe₂, AgGaTe₂ and AgInTe₂. Those skilled in the art will appreciate that the use of various other compound thin films are possible. In brief, the reason is because elements of the same Group on the Periodic Table have similar chemical properties.

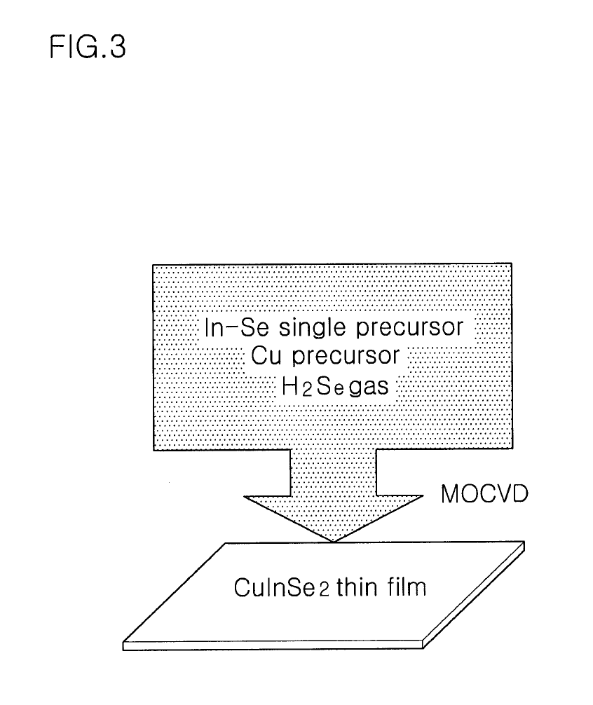

FIG. 3 is a schematic diagram illustrating an example of CuInSe₂ compound thin film formation according to a first embodiment of the present invention.

As shown in FIG. 3, an In and Se-containing single precursor, a monovalent copper (Cu) precursor, and a Se-containing precursor or gas are concurrently supplied to the substrate and subjected to MOCVD to form a CuInSe₂ compound thin film through a single-step process.

Unlike the prior art, the method for producing solar cell absorbing layers according to the present invention allows CIS compounds to begin to develop in the form of thin films at an early development stage and CIS compound thin films with an even surface can thus be obtained.

By partially replacing one constituent element of a ternary compound with another element from the same Group of the Periodic Table, an energy band gap of the compound can be varied. For example, CIS has potential utilization in a solar cell absorbing layer due to the high optical absorption coefficient thereof, as compared to other semiconductor compounds. However, since CIS has a relatively low energy band gap (about 1 eV), solar cells produced from the CIS cannot realize maximum efficiency due to a large short current (Isc) but a low open voltage (Voc). In order to maximize efficiency, there is a need for semiconductors that have a higher energy band gap while maintaining a high optical absorption coefficient. To obtain such a semiconductor, by partially replacing constituent elements of the semiconductor with elements having a smaller atomic radius selected from the same Group on the Periodic Table, the energy band gap can be varied depending upon the replacement ratio. This relation is represented by the following formula. For example, when Group III elements are partially replaced with III′ elements, the ternary compound is represented by the Formula, “I-III₁₋ₓIII′ₓ-VI₂”. When Group VI elements are partially replaced with VI′ elements, the ternary compound is represented by the formula “I-III-(VI_{1-y}VI′_{y})₂”. When Group III elements and Group VI elements are partially replaced with III′ and VI′ elements, respectively, the ternary compound is represented by the formula, I-III₁₋ₓIII′ₓ-(VI_{1-y}VI′_{y})₂. In the formulae, x and y are each independently in the range of 0 to 1. Such a compound is referred to as a “solid solution” of ternary compounds. These compounds can be readily prepared according to the following embodiment within the scope of the present invention.

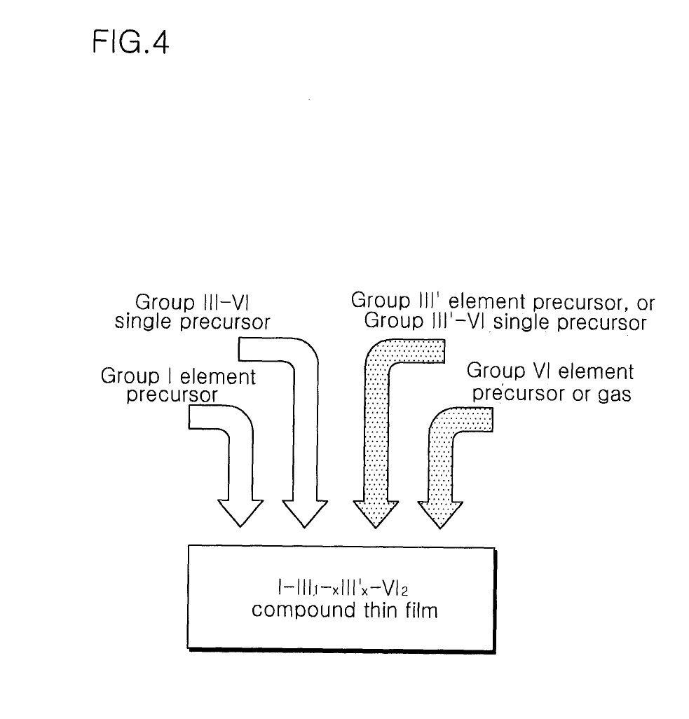

FIG. 4 is a schematic diagram illustrating a method for producing the I-III₁₋ₓIII′ₓ-VI₂ compound thin film according to a second embodiment of the present invention.

As shown in FIG. 4, according to the second embodiment of the present invention, in the process of developing a I-III-VI₂ compound thin film on a substrate using a Group III element and VI element-containing single precursor, a Group I metal-containing precursor, and a Group VI element-containing precursor or gas by a single MOCVD process, a Group III′ element different from the Group III element is further supplied thereto and deposited thereon, thereby forming an I-III₁₋ₓIII′ₓ-VI₂ compound thin film through a single MOCVD process.

Herein, the Group III element and VI element-containing single precursor, the Group I metal-containing precursor, and the Group VI element-containing precursor or gas are defined as in the aforementioned first embodiment. As such, a more detailed explanation thereof is omitted.

The second embodiment is different from the first embodiment in that the Group III′ element-containing precursor is further used. The Group III′ element is distinguished from the aforementioned Group III element in that it belongs to the same Group on the Periodic Table, but has a different in atomic number.

The Group III′ element-containing precursor may be selected from those commonly used in the art that have a structure of R₃M (wherein R is C₁-C₆ alkyl and M is a Group III metal element selected from Al, In and Ga). For example, the R₃M precursor is selected from (C₂H₅)₃Al (i.e. TEtAl), (CH₃)₃Al (i.e. TMeAl), (C₂H₅)₃In (i.e. TEtIn), (CH₃)₃In (i.e. TMeIn), (C₂H₅)₃Ga (i.e. TEtGa) and (CH₃)₃Ga (i.e. TMeGa), in which TMe is tri-methyl and TEt is tri-ethyl.

The Group III′ element-containing precursor may be a Group III′ and Group VI element-containing single precursor. The single precursor may be selected from those that have a structure of [R₂M(μ-ER′)]₂, wherein M is a Group III metal element selected from In, Ga and Al; R and R′ are each independently C₁-C₆ alkyl; E is a Group VI chalcogen element selected from S, Se and Te; and μ indicates a double-bond between the Group VI element and the Group III element.

As such, when the Group III′ element-containing precursor is used in the formation of the thin film, the Group III elements of the I-III-VI₂ compound thin film are partially replaced by the Group III′ element to form an I-III₁₋ₓIII′ₓ-VI₂ (0≦x≦1) compound thin film.

As mentioned in the first embodiment, the second embodiment of the present invention also enables mass-production at low cost and development of an I-III₁₋ₓIII′ₓ-VI₂ compound thin film in the form of single crystals from an early development stage. In addition, a high-quality final I-III₁₋ₓIII′ₓ-VI₂ compound thin film with few pores and an even surface can be obtained.

Examples of the I-III₁₋ₓIII′ₓ-VI₂ compound thin film thus formed include CuIn₁₋ₓGaₓSe₂, CuIn₁₋ₓAlₓSe₂, CuGa₁₋ₓAlₓSe₂, AgIn₁₋ₓGaₓSe₂, AgIn₁₋ₓAlₓSe₂, AgIn₁₋ₓGaₓSe₂, CuIn₁₋ₓGaₓS₂, CuIn₁₋ₓAlₓS₂, CuGa₁₋ₓAlₓS₂, AgIn₁₋ₓGaₓS₂, AgIn₁₋ₓAlₓS₂, AgIn₁₋ₓGaₓS₂, CuIn₁₋ₓGaₓTe₂, CuIn₁₋ₓAlₓTe₂, CuGa₁₋ₓAlₓTe₂, AgIn₁₋ₓGaₓTe₂, AgIn₁₋ₓAlₓTe₂, AgIn₁₋ₓGaₓTe₂, and the like. Those skilled in the art will appreciate that various other compound thin films are possible. In brief, the reason is because elements of the same Group on the Periodic Table have similar chemical properties.

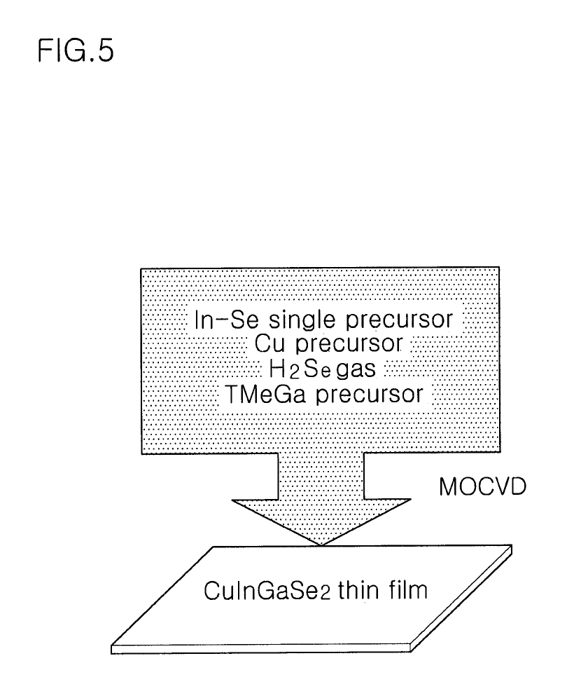

FIG. 5 is a schematic diagram illustrating one example of CuIn₁₋ₓGaₓSe₂ compound thin film production according to the second embodiment of the present invention. As shown in FIG. 5, in the process of developing a CIS thin film on a substrate, in which an indium (In) and selenium (Se)-containing single precursor, a monovalent copper (Cu) precursor, and a Se-containing precursor or gas are concurrently supplied to the substrate and subjected to MOCVD, a Ga-containing precursor is further supplied thereto and deposited thereon, thereby obtaining a CuIn₁₋ₓGaₓSe₂ (0≦x≦1) compound thin film.

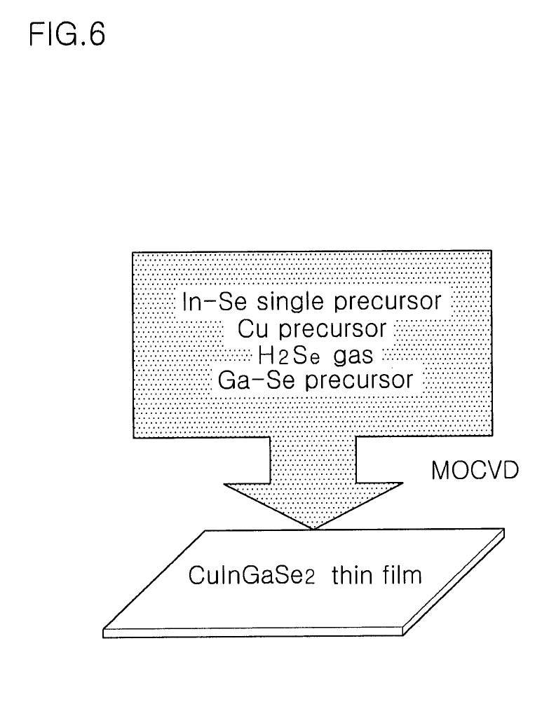

FIG. 6 is a schematic diagram illustrating another example of CuIn₁₋ₓGaₓSe₂ compound thin film production according to the second embodiment of the present invention. As shown in FIG. 6, in the process of developing a CIS thin film on a substrate by MOCVD, wherein an indium (In) and selenium (Se)-containing single precursor, a monovalent copper (Cu) precursor, and a Se-containing precursor or gas are concurrently supplied to the substrate and subjected to MOCVD, a Ga and Se-containing precursor is further supplied thereto and deposited thereon, thereby obtaining a CuIn₁₋ₓGaₓSe₂ (0≦x≦1) compound thin film.

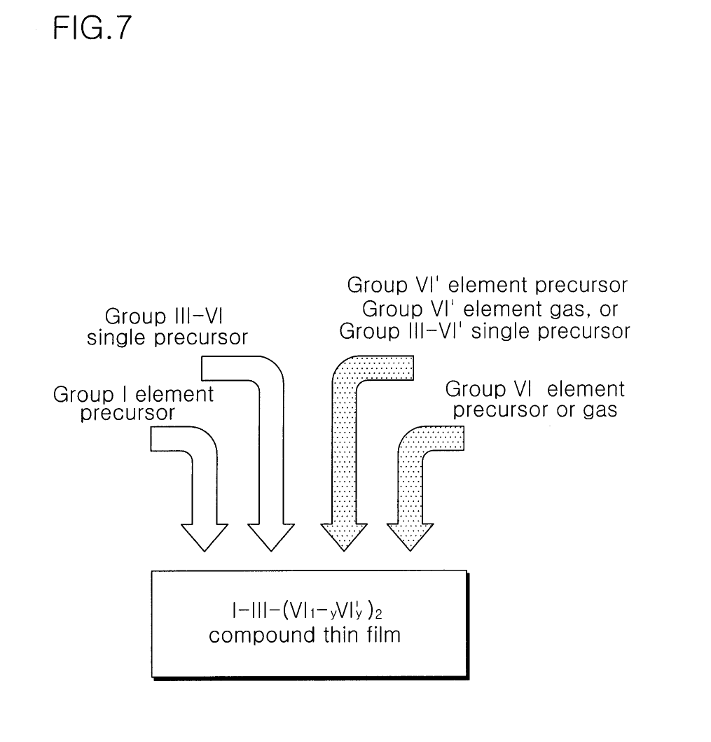

FIG. 7 is a schematic diagram illustrating a method for producing an I-III-(VI_{1-y}-VI′_{y})₂ compound thin film according to a third embodiment of the present invention.

As shown in FIG. 7, according to the third embodiment, in the process of developing an I-III-VI₂ compound thin film on a substrate using a Group III and VI element-containing single precursor, a Group I metal-containing precursor, and a Group VI element-containing precursor or gas by MOCVD, a precursor or gas containing a Group VI′ element different from the Group VI element is further supplied thereto and deposited thereon, thereby forming an I-III-(VI_{1-y}-VI′_{y})₂ compound thin film through a single MOCVD process.

Herein, the Group III element and VI element-containing single precursor, the Group I metal-containing precursor, the Group VI element-containing precursor, and the Group VI element-containing precursor or gas are defined as in the aforementioned first embodiment. Thus, a more detailed explanation thereof is omitted.

The third embodiment is different from the first embodiment in that a Group VI′ element-containing precursor or gas is further used. The Group VI′ element is distinguished from the aforementioned Group VI element in that they belong to the same Group on the Periodic Table, but differ in atomic number.

The Group VI′ element-containing precursor may be selected from those that have a structure of R₂E (wherein R is C₁-C₆ alkyl and E is a Group VI chalcogen element selected from S, Se and Te). Examples of the R₂E precursor include (C₂H₅)₂Se, (CH₃)₂Se, (C₂H₅)₂S, (CH₃)₂S, (C₂H₅)₂Te and (CH₃)₂Te, and those skilled in the art will appreciate that the use of other single precursors is possible.

The Group VI′ element-containing precursor may be a Group III and Group VI′ element-containing single precursor. The single precursor may be selected from those that have a structure of [R₂M(μ-ER′)]₂, wherein M is a Group III metal element selected from In, Ga and Al; R and R′ are each independently C₁-C₆ alkyl; E is a Group VI chalcogen element selected from S, Se and Te; and μ indicates a double-bond between the Group VI element and the Group III element.

The Group VI′ element-containing gas may be selected from those that have a structure of H₂E (wherein, E is a Group VI chalcogen element selected from Se, S and Te). Specifically, the Group VI element-containing gas is selected from H₂S, H₂Se and H₂Te.

As mentioned above, when the Group III and VI element-containing single precursor, the Group I metal-containing precursor, the Group VI element-containing precursor or the Group VI element-containing gas, and the precursor or gas containing a Group VI′ element different from the Group VI element are concurrently supplied to the substrate and subjected to MOCVD, the Group VI elements of the I-III-VI₂ compound thin film are partially replaced with the Group VI′ elements to form an I-III-(VI_{1-y}VI′_{y})₂ (0≦y≦1) compound thin film.

As mentioned in the first embodiment, the third embodiment of the present invention also enables mass-production at low cost and development of an I-III-(VI_{1-y}VI′_{y})₂ compound thin film in the form of single crystals at an initial development state. In addition, a high-quality final I-III-(VI_{1-y}VI′_{y})₂ compound thin film with few pores and an even surface can be obtained.

Examples of the I-III-(VI_{1-y}VI′_{y})₂ compound thin film include CuIn(Se_{1-y}S_{y})₂, CuAl(Se_{1-y}S_{y})₂, CuGa(Se_{1-y}S_{y})₂, AgIn(Se_{1-y}S_{y})₂, AgAl(Se_{1-y}S_{y})₂, AgGa(Se_{1-y}S_{y})₂, CuIn(Se_{1-y}Te_{y})₂, CuAl(Se_{1-y}Te_{y})₂, CuGa(Se_{1-y}Te_{y})₂, AgIn(Se_{1-y}Te_{y})₂, AgAl(Se_{1-y}Te_{y})₂, AgGa(Se_{1-y}Te_{y})₂, CuIn (S_{1-y}Te_{y})₂, CuAl(S_{1-y}Te_{y})₂, CuGa(S_{1-y}Te_{y})₂, AgIn (S_{1-y}Te_{y})₂, AgAl(S_{1-y}Te_{y})₂, AgGa(S_{1-y}Te_{y})₂, and the like. Those skilled in the art will appreciate that various other compound thin films are possible. In brief, the reason is because as elements of the same Group on the Periodic Table have similar chemical properties.

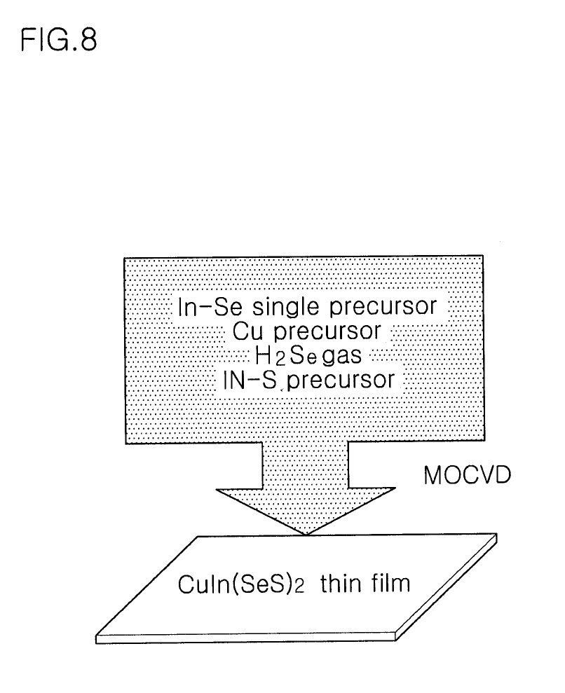

FIG. 8 is a schematic diagram illustrating one example of CuIn(Se_{1-y}S_{y})₂ compound thin film production according to the third embodiment of the present invention. As shown in FIG. 8, in the processing of developing a CIS thin film on a substrate by MOCVD, wherein an indium (In) and selenium (Se)-containing single precursor, a monovalent copper (Cu) precursor, and a Se-containing precursor or gas are concurrently supplied to the substrate and subjected to MOCVD, an In and S-containing precursor is further supplied thereto and deposited thereon, thereby obtaining a CuIn(Se_{1-y}S_{y})₂ (0≦y≦1) compound thin film.

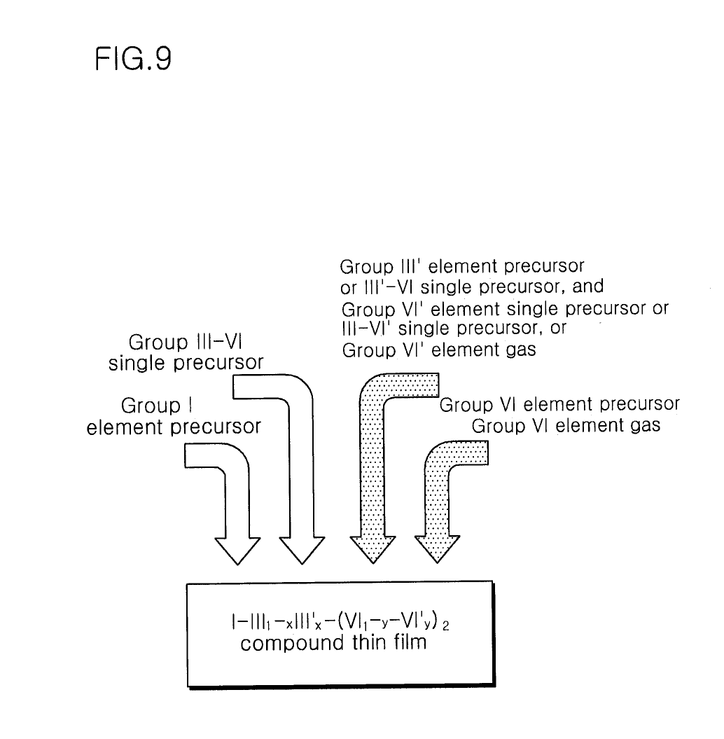

FIG. 9 is a schematic diagram illustrating a method for producing an I-III₁₋ₓIII′ₓ-(VI_{1-y}-VI′_{y})₂ compound thin film according to a fourth embodiment of the present invention.

As shown in FIG. 9, according to the second embodiment, in the process of developing an I-III-VI₂ compound thin film on a substrate through a single MOCVD process, wherein a Group III and Group VI element-containing single precursor, a Group I metal-containing precursor, and a Group VI element-containing precursor or gas are concurrently supplied to the substrate and subjected to MOCVD, a Group III′ element-containing precursor and a Group VI′ element-containing precursor or gas are further supplied thereto and deposited thereon, thereby forming an I-III₁₋ₓIII′ₓ-(VI_{1-y}-VI′_{y})₂ compound thin film.

Herein, the Group III element and VI element-containing single precursor, the Group I metal-containing precursor, the Group VI element-containing precursor and the Group VI element-containing precursor are defined as in the aforementioned first embodiment. Thus, a more detailed explanation thereof is omitted.

The fourth embodiment is different from the first embodiment in that a Group III′ element-containing precursor and a Group VI′ element-containing precursor or gas are further used. The Group III′ and VI′ elements are distinguished from the aforementioned Group III and VI elements, respectively, in that they belong to the same Group on the Periodic Table, but have different atomic numbers.

The Group III′ element-containing precursor may be selected from those commonly used in the art that have a structure of R₃M (wherein R is C₁-C₆ alkyl and M is a Group III metal element selected from Al, In and Ga). For example, the R₃M precursor is selected from (C₂H₅)₃Al (i.e. TEtAl), (CH₃)₃Al (i.e. TMeAl), (C₂H₅)₃In (i.e. TEtIn), (CH₃)₃In (i.e. TMeIn), (C₂H₅)₃Ga (i.e. TEtGa) and (CH₃)₃Ga (i.e. TMeGa), in which TMe is tri-methyl and TEt is tri-ethyl.

The Group III′ element-containing precursor may be a single precursor containing a Group III′ element and a Group VI element, or a single precursor containing a Group III′ element and a Group VI′ element. The single precursor may be selected from those that have a structure of [R₂M(μ-ER′)]₂, wherein M is a Group III metal element selected from In, Ga and Al; R and R′ are each independently C₁-C₆ alkyl; E is a Group VI chalcogen element selected from S, Se and Te; and μ indicates a double-bond between the Group VI element and the Group III element.

The Group VI′ element-containing precursor may have a structure of R₂E (wherein E is a Group VI chalcogen element selected from S, Se and Te; and R is C₁-C₆ alkyl). Examples of the R₂E precursor include (C₂H₅)₂Se, (CH₃)₂Se, (C₂H₅)₂S, (CH₃)₂S, (C₂H₅)₂Te and (CH₃)₂Te, and those skilled in the art will appreciate that the use of other single precursors is possible.

The Group VI′ element-containing precursor may be a Group III′ and Group VI element-containing single precursor, or a Group III′ and Group VI′ element-containing single precursor. Such a single precursor may be selected from those that have a structure of [R₂M(μ-ER′)]₂, wherein M is a Group III metal element selected from In, Ga and Al; R and R′ are each independently C₁-C₆ alkyl; E is a Group VI chalcogen element selected from S, Se and Te; and μ indicates a double-bond between the Group VI element and the Group III element.

The Group VI′ element-containing gas may be selected from those that have a structure of H₂E (wherein, E is a Group VI chalcogen element selected from Se, S and Te). Specifically, the Group VI element-containing gas is selected from H₂S, H₂Se and H₂Te.

As mentioned above, in the process of developing an I-III-VI₂ compound thin film on a substrate through a simple MOCVD process, wherein the Group III and Group VI element-containing single precursor, the Group I metal-containing precursor, and the Group VI element-containing precursor or the Group VI element-containing gas are concurrently supplied to the substrate and subjected to MOCVD, the Group III′ element-containing precursor and the Group VI′ element-containing precursor or gas are further supplied thereto and deposited thereon. As a result, the Group III and VI elements of the I-III-VI₂ compound thin film are partially replaced with the Group III′ and VI′ elements to form an I-III₁₋ₓIII′ₓ-(VI_{1-y}VI′_{y})₂ (0≦x, y≦1) compound thin film.

As mentioned in the first embodiment, the fourth embodiment of the present invention also enables mass-production at low cost and development of an I-III₁₋ₓIII′ₓ-(VI_{1-y}-VI′_{y})₂ thin film in the form of single crystals at an early development stage. In addition, a high-quality final I-III₁₋ₓIII′ₓ(VI_{1-y}-VI′_{y})₂ compound thin film with few pores and an even surface can be obtained.

Examples of the I-III₁₋ₓIII′ₓ-(VI_{1-y}-VI′_{y})₂ compound thin film thus obtained include CuIn₁₋ₓGaₓ(Se_{1-y}S_{y})₂, CuIn₁₋ₓ Alₓ(Se_{1-y}S_{y})₂, CuGa₁₋ₓAlₓ(Se_{1-y}S_{y})₂, AgIn₁₋ₓGaₓ(Se_{1-y}S_{y})₂, AgIn₁₋ₓAlₓ(Se_{1-y}S_{y})₂, AgIn₁₋ₓGaₓ(Se_{1-y}S_{y})₂, CuIn₁₋ₓGaₓ(Se_{1-y}Te_{y})₂, CuIn₁₋ₓAlₓ(Se_{1-y}Te_{y})₂, CuGa₁₋ₓAlₓ(Se_{1-y}Te_{y})₂, AgIn₁₋ₓGaₓ(Se_{1-y}Te_{y})₂, AgIn₁₋ₓAlₓ(Se_{1-y}Te_{y})₂, AgIn₁₋ₓGaₓ(Se_{1-y}Te_{y})₂, CuIn₁₋ₓGaₓ(S_{1-y}Te_{y})₂, CuIn₁₋ₓAlₓ(S_{1-y}Te_{y})₂, CuGa₁₋ₓAlₓ(S_{1-y}Te_{y})₂, AgIn₁₋ₓGaₓ(S_{1-y}Te_{y})₂, AgIn₁₋ₓAlₓ(S_{1-y}Te_{y})₂, AgIn₁₋ₓGaₓ(S_{1-y}Te_{y})₂, and the like. Those skilled in the art will appreciate that various other compound thin films are possible. In brief, the reason is because elements which belong to the same Group on the Periodic Table have similar chemical properties to one another.

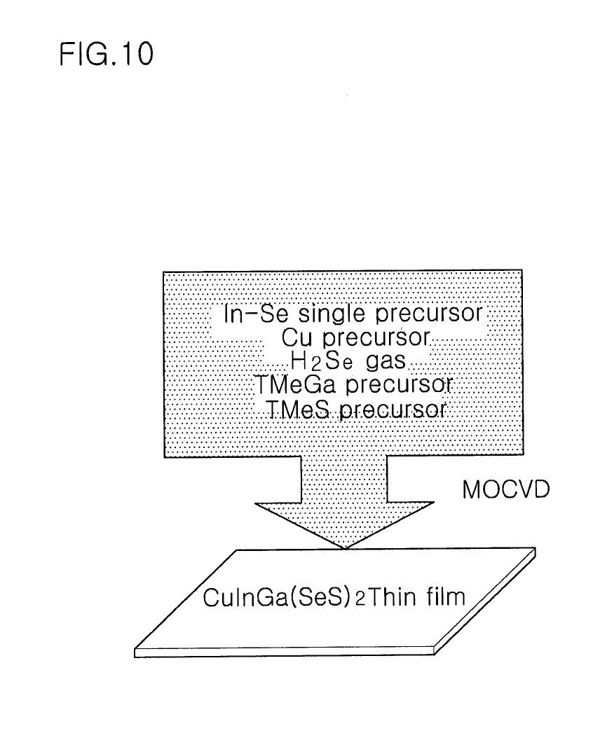

FIG. 10 is a schematic diagram illustrating one example of CuIn₁₋ₓGaₓ(Se_{1-y}S_{y})₂ compound thin film production according to the fourth embodiment of the present invention. As shown in FIG. 10, while an indium (In) and selenium (Se)-containing single precursor, a monovalent copper (Cu) precursor, a Se-containing gas, a Ga-containing precursor and a S-containing precursor are concurrently supplied to the substrate and subjected to MOCVD to produce a CuIn₁₋ₓGaₓ(Se_{1-y}S_{y})₂ (0≦x, y≦1) compound thin film.

The I-III-VI₂ compound thin film thus obtained may be widely utilized in a variety of applications including absorbing layers for solar cells according to properties of the thin film. The method of the present invention is advantageous in terms of improved economic and production efficiency due to the simplified thin film deposition process thereof.

Hereinafter, the present invention will be explained in more detail with reference to the following examples. However, these examples are given for the purpose of illustration and are not to be construed as limiting the scope of the invention.

### EXAMPLES

### Thin Film Production Example 1

A low-pressure MOCVD system was prepared, which included two bubblers containing [Me₂In(μ-SeMe)]₂ as an indium-selenium (In—Se) single precursor and (hfac)Cu(DMB) as a monovalent copper (Cu) precursor, respectively, and a H₂Se gas supplier to supply selenium (Se). A CuInSe₂ compound thin film was produced by operating the bubblers and the gas supplier according to the following process.

The [Me₂In(μ-SeMe)]₂, the H₂Se gas and (hfac)Cu(DMB) were substantially concurrently introduced to a soda glass substrate provided with a molybdenum (Mo) electrode at 450° C. to form a CuInSe₂ compound thin film. The precursors and gas were substantially concurrently supplied in the order of [Me₂In(μ-SeMe)]₂, H₂Se, and (hfac)Cu(DMB).

### Thin Film Production Example 2

A low-pressure MOCVD system was prepared, which included three bubblers containing [Me₂In(μ-SeMe)]₂ as an indium-selenium (In—Se) single precursor, (hfac)Cu(DMB) as a monovalent copper (Cu) precursor, and TMGa((CH₃)₃Ga) as a gallium (Ga) precursor, respectively, and a H₂Se gas supplier to supply selenium (Se). A CuIn₁₋ₓGaₓSe₂ compound thin film was produced by operating the bubblers and the gas supplier according to the following process.

The [Me₂In(μ-SeMe)]₂, the H₂Se gas and (hfac)Cu(DMB) were substantially concurrently introduced to a soda glass substrate provided with a molybdenum (Mo) electrode at 450° C., and TMGa((CH₃)₃Ga) was then supplied thereto to form a CuIn₁₋ₓGaₓSe₂ compound thin film. The precursors and gas were substantially concurrently supplied in the order of [Me₂In(μ-SeMe)]₂, H₂Se, (hfac)Cu(DMB), and TMGa((CH₃)₃Ga).

### Thin Film Production Comparative Example

A low-pressure MOCVD system was prepared, which included two bubblers containing [Me₂In(μ-SeMe)]₂ as an indium-selenium (In—Se) single precursor and (hfac)Cu(DMB) as a monovalent copper (Cu) precursor, respectively, and a H₂Se gas supplier to supply selenium (Se). A CuInSe₂ compound thin film was produced by operating the bubblers and the gas supplier according to the following process.

Indium (In) and selenium (Se) were deposited on a soda glass substrate, on which molybdenum (Mo) had been deposited as a rear electrode, at 320° C. by low-pressure MOCVD employing [Me₂In(μ-SeMe)]₂ as an In—Se single precursor to form an InSe thin film, copper (Cu) was deposited on the InSe thin film at 150° C. by low-pressure MOCVD employing (hfac)Cu(DMB) as a monovalent Cu precursor to form a Cu—In—Se compound thin film, and the Cu—In—Se thin film was heated at 450° C. under a H₂Se gas atmosphere to form a CuInSe₂ compound thin film.

### Experimental Example 1

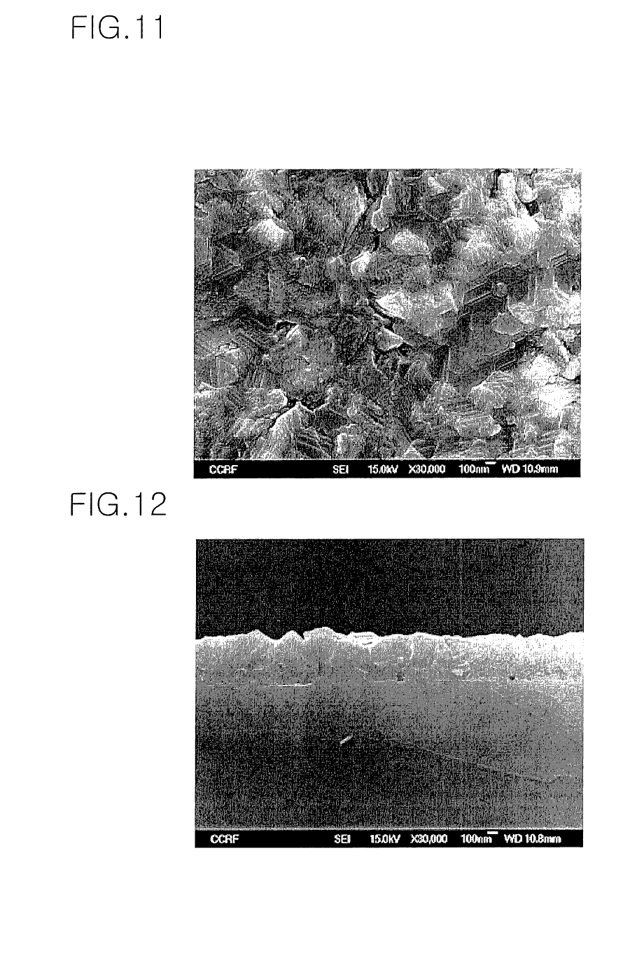

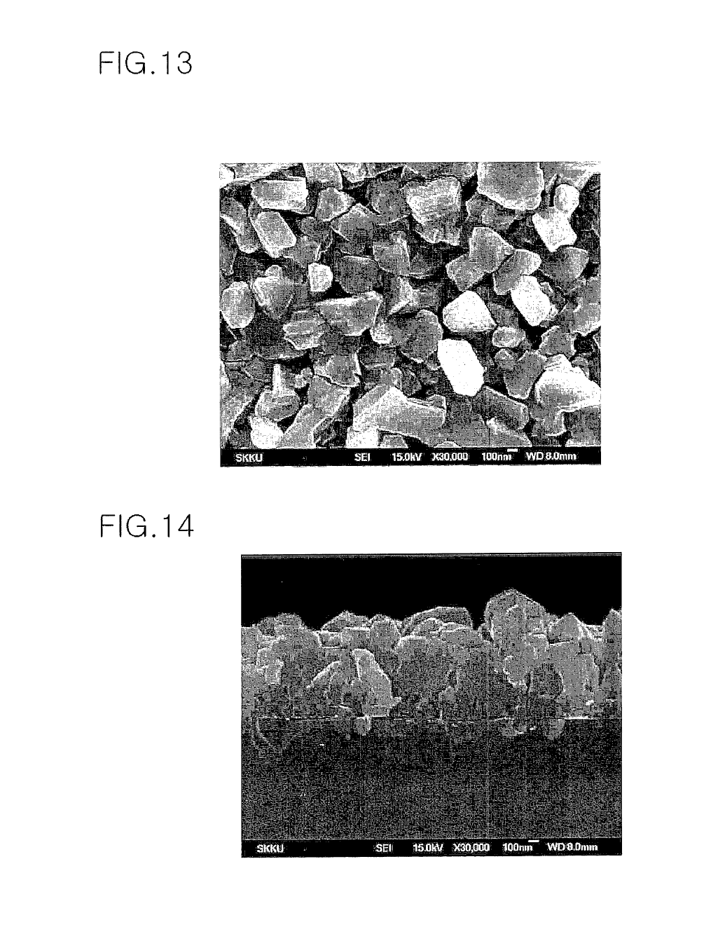

The surface and cross-section of the CuInSe₂ thin film produced in Thin Film Production Example 1 and Thin Film Production Comparative Example were observed by scanning electron microscope (SEM). The SEM surface and cross-section images of the CuInSe₂ thin film produced in Thin Film Production Example 1 are shown in FIGS. 11 and 12, respectively. The SEM surface and cross-section images of the CuInSe₂ thin film produced in Thin Film Production Comparative Example are shown in FIGS. 13 and 14, respectively.

As can be seen from FIGS. 11 to 14, the SEM images of the thin film produced according to the present invention show that the CuInSe₂ thin film has an even surface, no pores, and a well-developed crystal structure, and on the other hand, the SEM images of the thin film obtained by the conventional method show that the CuInSe₂ thin film has a well-developed crystal structure, but has inner pores and uneven surface.

### Experimental Example 2

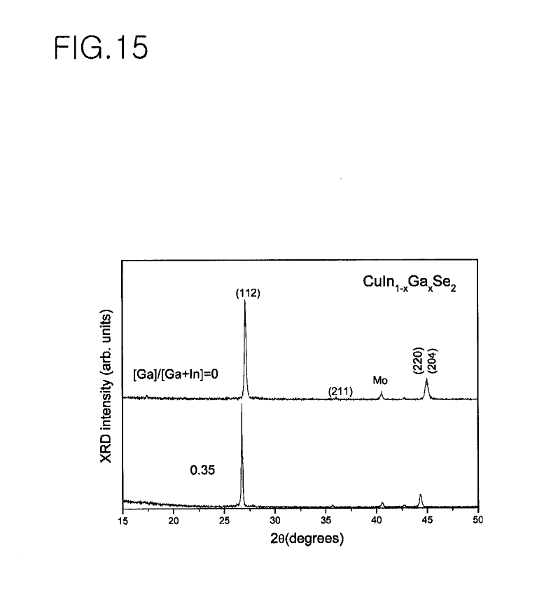

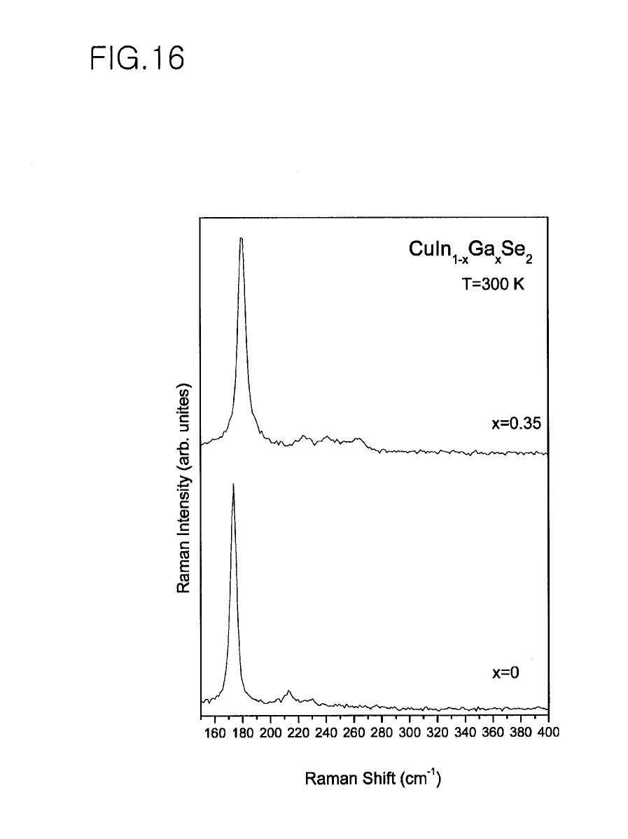

The XRD patterns and Raman spectra of the CuInSe₂ thin film and CuIn_{0.65}Ga_{0.35}Se₂ (x=0.35) developed in Thin Film Production Examples 1 and 2 are shown in FIGS. 15 and 16.

The XRD patterns of the developed CuInSe₂ thin film shown in FIG. 15 correspond to those of a commonly known CuInSe₂ single crystal. This result indicates that the developed thin film has a tetragonal single crystal structure. The lattice constants of the CuInSe₂ thin film are a=5.76 Å and c=11.46 Å which are consistent with previously reported results. In the XRD patterns of the CuInSe₂ thin film, the peaks at 2θ=26.77° and 35.74° correspond to the planes (112) and (211), respectively, and the peak at 2θ=44.42° corresponds to the plane (220/204).

In addition, a composition of indium (In) and gallium (Ga) that constitute the CIGS thin film obtained in Thin Film Production Example 2 was analyzed by X-ray fluorescence (XRF). As a result, the ratio [Ga]/[In+Ga] was 0.35. As a composition of the Group III metal elements, i.e., the value [Ga]/[In+Ga], increases, 2θ plotted at the peak assigned to the plane (112) in the XRD pattern gradually shifts right. (i.e., gradually increases). This is the reason that aA ratio of Ga atoms replacing In atoms increases due to the relatively smaller-size of the Ga atoms, thus decreasing the lattice constant. As the composition of [Ga]/[In+Ga] increases, the lattice constants 2a and c linearly decrease. In addition, the lattice constants of the CuIn_{0.65}Ga_{0.35}Se₂ thin film were a=5.612 Å and c=10.953 Å and a composition of the ratio [Ga]/[In+Ga] obtained from the lattice constants was thus 0.32, which is consistent with the XRF analysis result within standard deviation.

In the XRD patterns of the CuIn_{0.65}Ga_{0.35}Se₂ thin film, the peaks at 2θ=27.05° and 36.07° correspond to the planes (112) and (211), respectively, and the peak at 2θ=44.97° corresponds to the plane (220/204). The peaks at 2θ=44.49° observed in all XRD patterns are attributed to the Mo substrate.

As shown in FIG. 16, in the Raman spectra of CuInSe₂, the peaks at 175 cm⁻¹ and 214 cm⁻¹ are an A₁ mode and the highest B₂ (TO) mode, respectively, according to Tanino et. al. In the Raman spectra of the CuIn_{0.65}Ga_{0.35}Se₂ thin film, the peaks at 179 cm⁻¹ and 217 cm⁻¹ are an A₁ mode and the highest B₂ (TO) mode, respectively. These phonon energies shift to higher values, as compared to the case of the CuInSe₂ thin film. This is the reason that smaller-size of gallium (Ga) atoms partially replace indium (In) atoms, thus increasing the vibrational energy of the corresponding lattice vibration mode.

The present invention has been explained in more detail with reference to preferred embodiments. However, these examples are not to be construed as limiting the scope of the inventive concept. More specifically, although production processes of thin films composed of CuInSe₂ and CuIn_{0.65}Ga_{0.35}Se₂ compounds were given as representative embodiments, these compounds are provided herein for purposes of illustration only of I-III-VI₂ compounds selected from Group I, III and VI elements on the Periodic Table and are not intended to limit the scope of the invention.

As apparent from the foregoing, the method for producing an I-III-VI₂ compound thin film according to the present invention employs a single deposition process to form a final thin film and thus provides an economical, simplified process, as compared to conventional methods. In addition, the method is capable of producing a thin film with an even surface and few or no inner pores, and advantageously, is thus useful as a light-absorbing layer for a solar cell.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A method for producing a I-III-VI2 compound thin film on a substrate through a single Metal Organic Chemical Vapor Deposition (MOCVD) process,
wherein a Group III and Group VI element-containing single precursor, a Group I metal-containing precursor, and a Group VI element-containing precursor or a Group VI element-containing gas are concurrently supplied to a substrate and subjected to MOCVD to form a I-III-VI₂ compound thin film on the substrate.

2. The method according to claim 1, wherein the Group III and VI element-containing single precursor has a structure of [R₂M(μ-ER′)]₂, in which M is a Group III metal element selected from In, Ga and Al; R and R′ are each independently C₁-C₆ alkyl; E is a Group VI chalcogen element selected from S, Se and Te; and μ indicates a double-bond between the Group VI element and the Group III element.

3. The method according to claim 1, wherein the Group I metal-containing precursor is a monovalent Cu precursor having a structure of (hfac)I(DMB), in which hfac is an abbreviation for hexafluoroacetylaceto and DMB is an abbreviation for 3,3-dimethyl-1-butene.

4. The method according to claim 3, wherein the Group VI element-containing precursor has a structure of R₂E, in which E is a Group VI chalcogen element selected from S, Se and Te; and R is C₁-C₆ alkyl.

5. The method according to claim 3, wherein the Group VI element-containing gas has a structure of H₂E, in which E is a Group VI chalcogen element selected from Se, S and Te.

6. A method for producing a I-III-VI₂ compound thin film on a substrate through a single Metal Organic Chemical Vapor Deposition (MOCVD) process,
wherein a Group III element and Group VI element-containing single precursor, a Group I metal-containing precursor, and a Group VI element-containing precursor or a Group VI element-containing gas are concurrently supplied on a substrate and subjected to MOCVD to form a I-III-VI₂ compound thin film on the substrate,
wherein the I-III-VI₂ compound thin film is an compound thin film and the I-III₁₋ₓIII′ₓ-VI₂ compound thin film is formed by supplying and depositing a precursor containing a Group III′ element different from the Group III element onto the resulting thin film during the thin film formation process.

7. The method according to claim 6, wherein the Group III′ element-containing precursor has a structure of R₃M, in which R is C₁-C₆ alkyl and M is a Group III metal element selected from Al, In and Ga.

8. The method according to claim 6, wherein the Group III′ element-containing precursor is a single precursor containing a Group III′ element and a Group VI element and the single precursor has a structure of [R₂M(μ-ER′)]₂, in which M is a Group III metal element selected from In, Ga and Al; R and R′ are each independently C₁-C₆ alkyl; E is a Group VI chalcogen element selected from S, Se and Te; and μ indicates a double-bond between the Group VI element and the Group III element.

9. The method according to claim 6, wherein the Group III and Group VI element-containing single precursor has a structure of [R₂M(μ-ER′)]₂, in which M is a Group III metal element selected from In, Ga and Al; R and R′ are each independently C₁-C₆ alkyl; E is a Group VI chalcogen element selected from S, Se and Te; and μ indicates a double-bond between the Group VI element and the Group III element.

10. The method according to claim 6, wherein the Group I metal-containing precursor is a monovalent Cu precursor having a structure of (hfac)I(DMB), in which hfac is an abbreviation for hexafluoroacetylaceto and DMB is an abbreviation for 3,3-dimethyl-1-butene.

11. The method according to claim 10, wherein the Group VI element-containing precursor has a structure of R₂E, in which E is a Group VI chalcogen element selected from S, Se and Te; and R is C₁-C₆ alkyl.

12. The method according to claim 10, wherein the Group VI element-containing gas has a structure of H₂E, in which E is a Group VI chalcogen element selected from Se, S and Te.

13. A method for producing a I-III-VI₂ compound thin film on a substrate through a single Metal Organic Chemical Vapor Deposition (MOCVD) process,
wherein a Group III and Group VI element-containing single precursor, a Group I metal-containing precursor, and a Group VI element-containing precursor or a Group VI element-containing gas are concurrently supplied to a substrate and subjected to MOCVD to form a I-III-VI₂ compound thin film on the substrate,
wherein the I-III-VI₂ compound thin film is an I-III-(VI_{1-y}-VI′_{y})₂ compound thin film and the I-III-(VI_{1-y}-VI′_{y})₂ compound thin film is formed by supplying and depositing a precursor containing a Group VI′ element different from the Group VI element or a gas containing the Group VI′ element onto the resulting thin film during the thin film formation process.

14. The method according to claim 13, wherein the Group VI′ element-containing precursor has a structure of R₂E, in which E is a Group VI chalcogen element selected from S, Se and Te; and R is C₁-C₆ alkyl.

15. The method according to claim 13, wherein the Group VI′ element-containing precursor has a single precursor containing a Group III element and a Group VI′ element and the single precursor has a structure of [R₂M(μ-ER′)]₂, in which M is a Group III metal element selected from In, Ga and Al; R and R′ are each independently C₁-C₆ alkyl; E is a Group VI chalcogen element selected from S, Se and Te; and μ indicates a double-bond between the Group VI element and the Group III element.

16. The method according to claim 13, wherein the Group VI′ element-containing gas has a structure of H₂E, in which E is a Group VI chalcogen element selected from Se, S and Te.

17. The method according to claim 13, wherein the Group III and Group VI element-containing precursor is a single precursor and the single precursor has a structure of [R₂M(μ-ER′)]₂, in which M is a Group III metal element selected from In, Ga and Al; R and R′ are each independently C₁-C₆ alkyl; E is a Group VI chalcogen element selected from S, Se and Te; and μ indicates a double-bond between the Group VI element and the Group III element.

18. The method according to claim 13, wherein the Group I metal-containing precursor is a monovalent Cu precursor having a structure of (hfac)I(DMB), in which hfac is an abbreviation for hexafluoroacetylaceto and DMB is an abbreviation for 3,3-dimethyl-1-butene.

19. The method according to claim 18, wherein the Group VI element-containing precursor has a structure of R₂E in which E is a Group VI chalcogen element selected from S, Se and Te; and R is C₁-C₆ alkyl.

20. The method according to claim 19, wherein the Group VI element-containing gas has a structure of H₂E, in which E is a Group VI chalcogen element selected from Se, S and Te.

21. A method for producing a I-III-VI₂ compound thin film on a substrate through a single Metal Organic Chemical Vapor Deposition (MOCVD) process,
wherein a Group III element and Group VI element-containing single precursor, a Group I metal-containing precursor, and a Group VI element-containing precursor or a Group VI element-containing gas are concurrently supplied to a substrate and subjected to MOCVD to form a I-III-VI₂ compound thin film on the substrate,
wherein the I-III-VI₂ compound thin film is an I-III₁₋ₓIII′ₓ-(VI_{1-y}-VI′_{y})₂ compound thin film and the I-III₁₋ₓIII′ₓ-(VI_{1-y}-VI′_{y})₂ compound thin film is formed by supplying and depositing a Group III′ element different from the Group III element-containing precursor and a Group VI′ element different from the Group VI element-containing precursor or gas onto the resulting thin film during the thin film formation process.

22. The method according to claim 21, wherein the Group III′ element-containing precursor has a structure of R₃M, in which R is C₁-C₆ alkyl and M is a Group III metal element selected from Al, In and Ga.

23. The method according to claim 21, wherein the Group III′ element-containing precursor is a single precursor containing a Group III′ element and a Group VI element, or a single precursor containing a Group III′ element and a Group VI′ element, and the single precursor has a structure of [R₂M(μ-ER′)]₂, in which M is a Group III metal element selected from In, Ga and Al; R and R′ are each independently C₁-C₆ alkyl; E is a Group VI chalcogen element selected from S, Se and Te; and μ indicates a double-bond between the Group VI element and the Group III element.

24. The method according to claim 21, wherein the Group VI′ element-containing precursor has a structure of R₂E, in which E is a Group VI chalcogen element selected from S, Se and Te; and R is C₁-C₆ alkyl.

25. The method according to claim 21, wherein the Group VI′ element-containing precursor is a single precursor containing a Group III element and a Group VI′ element, or a single precursor containing a Group III′ element and a Group VI′ element and the single precursor has a structure of [R₂M(μ-ER′)]₂, in which M is a Group III metal element selected from In, Ga and Al; R and R′ are each independently C₁-C₆ alkyl; E is a Group VI chalcogen element selected from S, Se and Te; and μ indicates a double-bond between the Group VI element and the Group III element.

26. The method according to claim 21, wherein the Group VI′ element-containing gas has a structure of H₂E, in which E is a Group VI chalcogen element selected from Se, S and Te.

27. The method according to claim 21, wherein the Group III element and Group VI element-containing single precursor has a structure of [R₂M(μ-ER′)]₂, in which M is a Group III metal element selected from In, Ga and Al; R and R′ are each independently C₁-C₆ alkyl; E is a Group VI chalcogen element selected from S, Se and Te; and μ indicates a double-bond between the Group VI element and the Group III element.

28. The method according to claim 21, wherein the Group I metal-containing precursor is a monovalent Cu precursor having a structure of (hfac)I(DMB), in which hfac is an abbreviation for hexafluoroacetylaceto and DMB is an abbreviation for 3,3-dimethyl-1-butene.

29. The method according to claim 28, wherein the Group VI element-containing precursor has a structure of R₂E, in which E is a Group VI chalcogen element selected from S, Se and Te; and R is C₁-C₆ alkyl.

30. The method according to claim 28, wherein the Group VI element-containing gas has a structure of H₂E, in which E is a Group VI chalcogen element selected from Se, S and Te.

31. (canceled)
